(19) United States
(12) Patent Application Publication
(10) Pub. No.: US 2003/0074623 A1
(43) Pub. Date: Apr. 17, 2003

(54) Algorithmic test pattern generator

(76) Inventor: Koji Takahashi, Santa Clara, CA (US)

Correspondence Address: MURAMATSU & ASSOCIATES, Suite 225, 7700 Irvine Center Drive, Irvine, CA, 92618, US

(21) Appl. No.: 09/976,790

(22) Filed: Oct. 13, 2001

(51) Int. Cl. G06F 11/00; G01R 31/28

(52) U.S. Cl. 714/738

(57) ABSTRACT

An algorithmic pattern generator for a semiconductor memory test system for generating test patterns to test semiconductor memory devices. The algorithmic pattern generator is a dedicated pattern generator structured by a field programmable logic device where at least one state machine is configured by applying a hardware program, thereby enabling to generate specified algorithmic test patterns. The field programmable logic device includes a plurality of synchronous circuit units each being structured by combinations of logic circuits and flip flops. The state machine is configured by combining the synchronous circuit units through the hardware program. The program applied to the field programmable logic device can be rewritable, thereby creating a pattern generator which is capable of generating a different algorithmic pattern.

### FIELD OF THE INVENTION

This invention relates to a test pattern generator for use in a semiconductor test system for testing semiconductor integrated circuits, and more particularly, to an algorithmic test pattern generator structured by a gate array such as a field programmable gate array (FPGA) for generating a specified test pattern.

### BACKGROUND OF THE INVENTION

FIG. 1 shows a typical structure of a semiconductor memory test system (may also refereed to as a “memory tester”) for testing a semiconductor memory integrated circuit (hereafter may also referred to as “DUT” or “memory device under test”.

In FIG. 1, a test processor (not shown) provided in the test system executes a main program 12. As a consequence, a test pattern generator 16 receives test data through a tester bus 13. Based on the test data from the test processor, the test pattern generator 16 generates pattern data (PD) which is provided to a wave formatter 20 through a data selector 18. Based on the test data, the test pattern generator 16 also generates timing data which is provided to a timing generator 14.

Based on the pattern data PD from the pattern generator 16 and the timing signals (i.e., clocks) from the timing generator 14, the wave formatter 20 produces a test pattern. The test pattern is then applied to a device under test (DUT) 24 through a driver 22.

When the device under test 24 is a semiconductor memory device, the test pattern provided to the memory device under test consists of an address pattern (APAT) which is typically address data, a data pattern (DPAT) which is write data, and a control signal pattern (CPAT) which controls the memory device. After writing the predetermined data in the predetermined addresses of the memory device under test, the data in that address locations is read to evaluate whether the stored data is the same as the write data.

More particularly, the data read out from the memory device under test 24 is converted to a logic signal with reference to predetermined threshold levels (VOH, VOL) by an analog comparator 26. The logic signal from the analog comparator 26 is then logically compared with expected value EXP (write data) generated by the pattern generator 16 by a logic (digital) comparator 28. The result of the comparison is stored in a failure memory (AFM) 30 at addresses which correspond to the addresses of the memory device under test 24 and will be used in the failure analysis thereafter.

Here, the address data or write data provided to the memory device under test for writing or reading the data can be patterns generated by sequences based on various mathematical algorithm. In such a pattern sequence based on mathematical algorithm, the same or similar portions of the pattern are repeated with a predetermined regularity. Such a pattern generation algorithm is selected based on a physical structure or a test purpose of the particular memory device under test. When the pattern generator 16 equips with a function for generating test patterns based on such mathematical algorithm, it is sometimes called an algorithmic test pattern generator (ALPG).

FIG. 2 is a block diagram showing a basic structure of the pattern generator 16. The pattern generator 16 in this example is structured by an address generator 100 for generating address patterns (APAT), a data generator 200 for generating data patterns (DPAT), a control signal generator 300 for generating control signal patterns (CPAT), and a sequence controller 500. The sequence controller 500 is structured by an instruction memory 44, a program counter 40, and a program counter controller 42.

The program counter 40 generates address data to be supplied to the instruction memory 44. Based on the command from the instruction memory 44, the program counter controller 42 controls the start locations and jump destinations of the address data to be generated by the program counter 40. The instruction memory 44 stores each command to be supplied to the address generator 100, the data generator 200, and the control signal generator 300 in predetermined addresses. Such data and instructions stored in the instruction memory 44 are supplied to the instruction memory 44 through the tester bus 13 from the main program 12 prior to the start of the test.

When testing a semiconductor memory, because of reasons such as physical structure, the memory device under test is known to be tested more accurately by applying test patterns with predetermined repetitive sequences. As mentioned above, such test patterns are called algorithmic test patterns, and various types of algorithmic test patterns have been proposed and used.

FIG. 3 shows a marching pattern, which is one of the typical algorithmic test patterns. In this example, it is assumed that the number of addresses (cell numbers) of the memory under test is only 8 (from address 0 to address 7) to simplify the description. In the upper portion of FIG. 3, the applicable addresses are expressed in a flow graph, where writing 0 in the memory is denoted by “0W”, writing 1 is denoted by “1W”, and reading 0 from the memory is denoted by “0R”, and reading 1 is denoted by “1R”, respectively. In the lower portion of FIG. 3, the addresses generated by the address generator, the data generated by the data generator, and the control signals generated by the control signal generator are respectively shown in a table form.

Even if the marching pattern of FIG. 3 is applied to the memory under test with only 8 memory cells, the test pattern requires 40 steps to be generated. Therefore, in order to test today's high density semiconductor memory devices with several hundred megabits, for example, an enormous amount of memory capacity will be necessary to simply store such test patterns in the memory of the pattern generator. Therefore, in the industry, the test pattern having predetermined repetitive sequences is generated by conducting mathematical computations, thereby making the memory capacity required for the pattern generation smaller. Such pattern generators are called an algorithmic pattern generator as mentioned above.

A structural example of the algorithmic pattern generator for generating the marching pattern of FIG. 3 is shown in FIG. 4. The pattern data required for generating the target algorithmic patterns is supplied to the pattern generator 16 from the main program 12 of FIG. 1 and stored in the instruction memory 44.

By the instructions in the addresses specified by the program counter, the instruction memory 44 controls the operation of the program counter through the program counter controller 42. For example, an initial value “8” is set in the program counter controller 42, where the program counter will count the clock eight times before shifting to the next address data. After this process, the next instruction set in the instruction memory 44 will be generated.

Through the sequences specified by the instruction memory 44, the address pattern to be applied to the DUT (memory under test) 22 is generated by the address generator 100. Also, the control of the write/read operation of the memory under test is conducted by the control signal generator 300 based on the control data (write “WI” or read “R”) in the instruction memory 44. Further, the control data includes data for specifying type of data (“1” or “0”) generated by the data generator 200. For example, data inversion (ex. from value “0” to “1”) is conducted by the control data “/D”.

The structure shown in the block diagram of FIG. 4 is a simple structure since it shows the case where the marching pattern of FIG. 3 is generated for only 8-bit addresses. However, an actual pattern generator is structured as a general purpose pattern generator where other various algorithmic patterns are generated as well as for generating a test pattern for a larger number of addresses. Therefore, to generate pattern sequences unique to each type of algorithmic pattern, the data to be stored in the instruction memory becomes extremely complicated. Further, many additional circuits have to be installed in the program counter controller, address generator, and data generator, resulting in a very large and complex structure.

As for such algorithmic patterns, other than the marching pattern mentioned above, there are a checker board pattern, a galloping pattern, a walking pattern, an inverse pattern, a diagonal inverse pattern, as well as various upgraded and modified versions of those patterns. Since the capacity of the recent memory device under test is very large and a pattern generator is so structured that the various algorithmic patterns noted above can be generated, an overall pattern generator is large and expensive.

As in the foregoing, the conventional algorithmic pattern generator is structured to generate every type of patterns in order to retain its versatility. However, in a case where semiconductor memories are actually tested by a user, for example, types of memories under test are only two or three. Therefore, in many situations, using only two or three kinds of algorithmic patterns in such tests will not create any problems in practical applications.

Further, the traditional algorithmic pattern generator produces test patterns by storing the data required for pattern generation in the instruction memory and consecutively reading and processing the data. Due to this configuration, generating the algorithmic patterns at high speed is difficult since it requires the time to access the memory to read the required data and instructions from the memory as well as the time to execute the read-out data and instructions.

### SUMMARY OF THE INVENTION

It is, therefore, an object of the present invention to provide an exclusive algorithmic pattern generator structured by a programmable logic device at a small scale and low cost to be used in a semiconductor test system where the pattern generator is limited to generate only specified algorithmic patterns.

Another object of the present invention is to provide an exclusive algorithmic pattern generator structured by using a programmable logic device where specified algorithmic patterns can be generated at high speed in order to test a semiconductor memory by a semiconductor test system.

A further object of the present invention is to provide an algorithmic pattern generator which is capable of hardware based program using an FPGA (field programmable gate array) and generating specific algorithmic patterns at high speed in order to test a semiconductor memory by a semiconductor test system.

A further object of the present invention is to provide an algorithmic pattern generator which is capable of changing the algorithmic pattern generated by using a programmable logic device that can rewrite programs, such as an FPGA, and changing the program therein, in order to test a semiconductor memory by a semiconductor test system.

The present invention is an algorithmic test pattern generator used in a semiconductor memory test system for generating test patterns to test semiconductor memory devices. The algorithmic test pattern of the present invention is a dedicated pattern generator structured by a field programmable logic device wherein at least one state machine is configured by applying a hardware based program thereto, thereby enabling to generate specified algorithmic test patterns.

The field programmable logic device includes a plurality of synchronous circuit units each being structured by combinations of logic circuits and flip flops. The state machine is configured by combining the synchronous circuit units through a hardware program. Depending on the type of field programmable logic device, the hardware program applied to the field programmable logic device can be rewritable, thereby creating a pattern generator of different structure which is capable of generating a different algorithmic pattern.

By creating the algorithmic pattern generator of the present invention with the use of a programmable logic device, the pattern generator for specific patterns can be established by a small scale hardware. Also, since the algorithmic pattern generator of the present invention performs a predetermined operation by the program assembled in the hardware, the time required to access the memory required for generating the test patterns by the conventional general purpose algorithmic patterns, is no longer necessary, thereby achieving the high-speed operation. Further, by using the type of programmable logic device whose program is rewritable for configuring the function, the algorithmic pattern can be changed by the hardware program.

### BRIEF DESCRIPTION OF THE DRAWINGS

FIG. 1 is a block diagram showing an example of basic structure of a semiconductor memory test system (memory tester).

FIG. 2 is a block diagram showing a basic structure of the pattern generator in the semiconductor memory test system of FIG. 1.

FIG. 3 is a schematic diagram showing an example of sequences in a marching pattern which is one of the types of algorithmic test patterns generated by the pattern generator for testing a semiconductor memory.

FIG. 4 is a block diagram showing a data structure and a structure of an algorithmic pattern generator required for generating the marching pattern of FIG. 3 in a conventional technology.

FIG. 5 is a schematic diagram showing a simplified structural example of an FPGA (field programmable gate array) which is one of the kinds of gate arrays used for establishing the algorithmic pattern generator of the present invention.

FIG. 6 is a circuit diagram showing an example of basic circuit structure in one of the logic cells in the FPGA of FIG. 5.

FIG. 7 is a block diagram showing an example of the algorithmic pattern generator of the present invention structured by an FPGA which is constituted to generate the marching pattern of FIG. 3.

FIGS. 8A and 8B are state diagrams showing the sequences for generating the marching pattern of FIG. 3 based on the algorithmic pattern generator of FIG. 7 structured by the FPGA.

FIG. 9A is a block diagram showing an example of structure in the sequencer 70 shown in FIG. 7, FIG. 9B is a block diagram showing an example of structure in the sequencer 72 of FIG. 7, and FIG. 9C is a block diagram showing an example of structure in the counter 74 shown in FIG. 7.

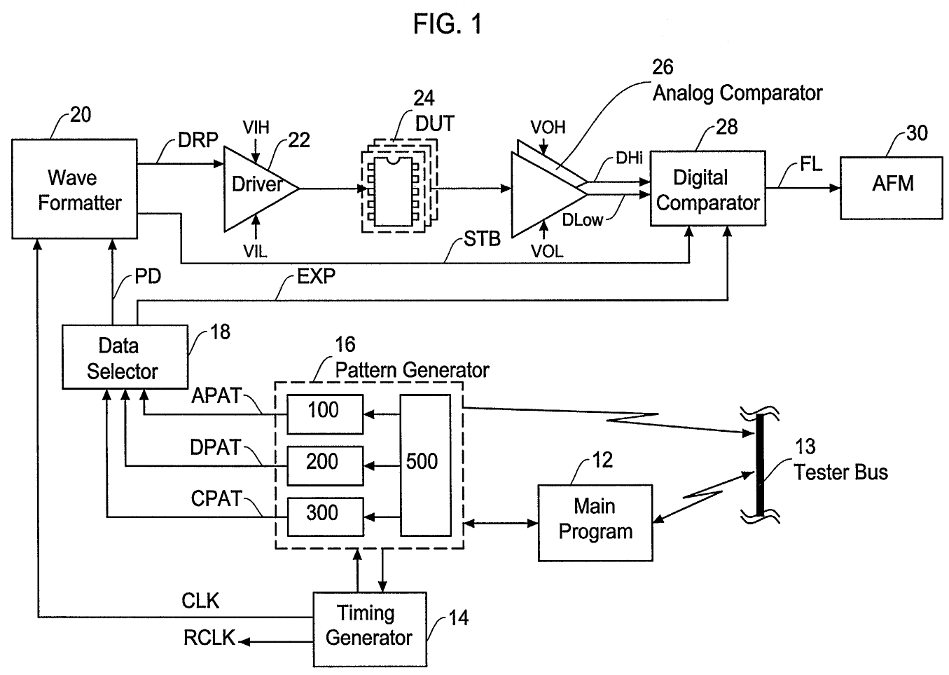

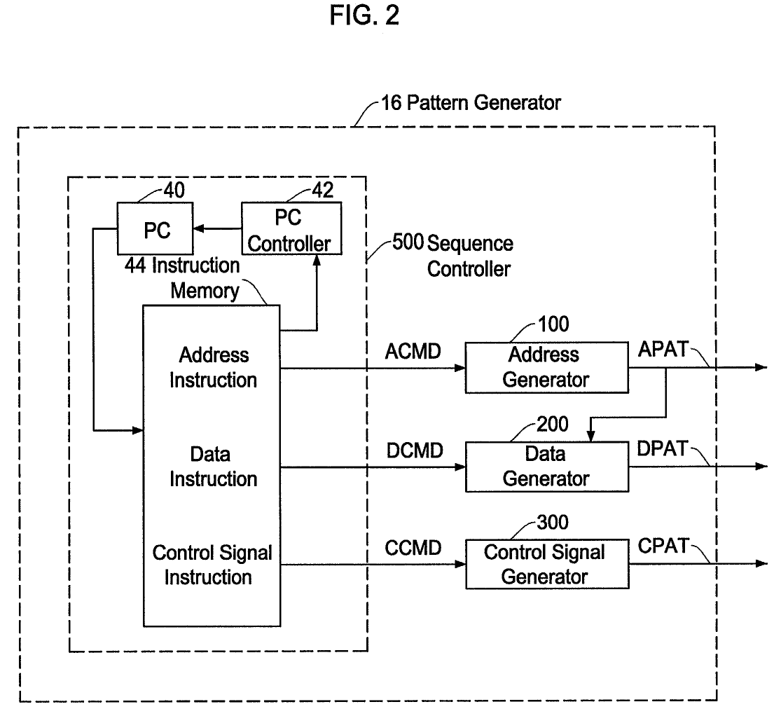

### DETAILED DESCRIPTION OF THE INVENTION

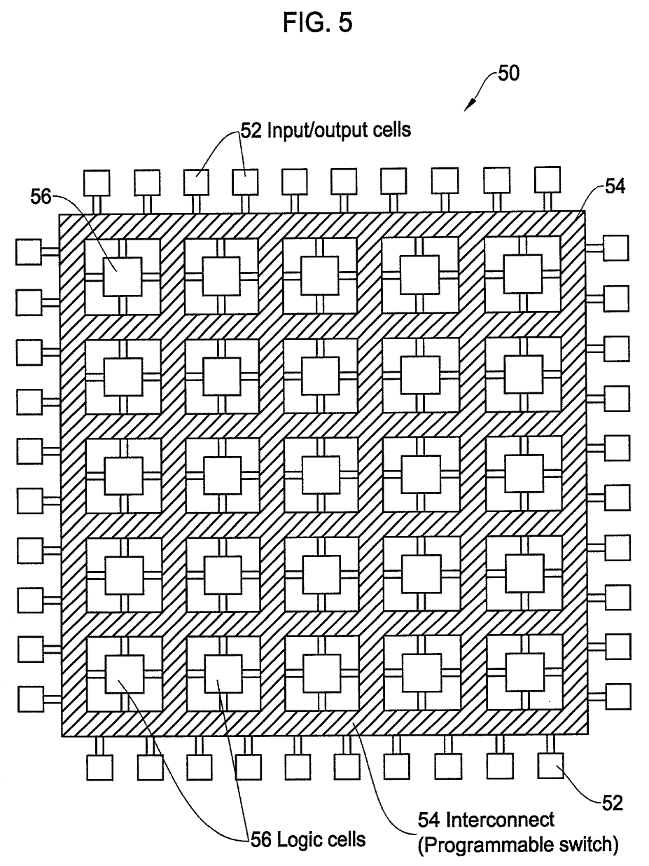

The algorithmic test pattern generator of the present invention will be explained with reference to FIGS. 5-9. The algorithmic test pattern generator of the present invention is structured as an exclusive algorithmic pattern generator for generating only specified algorithmic test patterns by using an FPGA (field programmable gate array), a PLD (programmable logic device), or a PAL (programmable array logic).

The FPGA, PLD, or PAL noted above is a logic IC device capable of being programmed by a user (programmable logic device), where the program by that user is loaded in the IC device to configurate the intended functions in the IC device. Such programmable logic devices used in the present invention are not limited to the nomenclatures such as the FPGA mentioned above, but includes every logic device capable of being programmed by a user.

FIG. 5 shows a basic structural example of the FPGA (field programmable gate array). In an FPGA 50, a large number of logic cells 56, such as several hundreds or several thousands, are arranged in a two-dimensional manner (in array). In each logic cell 56, channels are formed vertically and horizontally, where the input/output signal paths for the logic cells 56 are formed by these channels. These signal paths can be freely connected to other logic cells 56 through interconnects 54 (programmable switches). In the peripheral of the FPGA 50, input/output cells 52 are provided for interfacing with the external circuits.

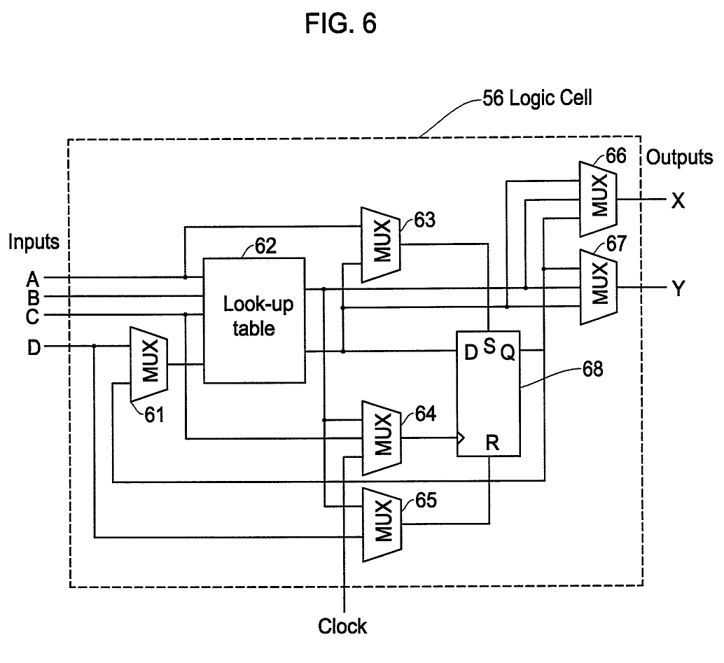

The most simplified structural example of each logic cell 56 of the FPGA 50 is shown in FIG. 6. In this example, the logic cell 56 has input terminals A, B, C, D, output terminals X, Y, and a clock terminal, where each terminal operates in synchronism with the clock. The inside of the logic cell 56 is comprised of a plurality of multiplexers (selector circuits) 61 and 63-67, a look-up table 62, and a flip flop 68.

The look-up table 62 is a small memory which is capable of being programmed by a user, where input signals from the above noted input terminals can be used as the addresses of the memory. By programming the look-up table 62, desired logic functions can be fulfilled in a manner similar to a PROM (programmable ROM). Therefore, it can be said that each of the logic cells 56 is a unit structured by logic circuits (formed of gates) and flip flops.

With respect to the programmable switches 54, there is a type of FPGA which is so structured that once the first programming is fixed, no further change is available, or another type of FPGA which is capable of repeatedly changing the program; and both are available in the market. In the case where the FPGA is capable of repeatedly changing the program (rewriting the program), the programmable switch 54 is structured by a transistor switch, and its on and off settings are controlled by external signals.

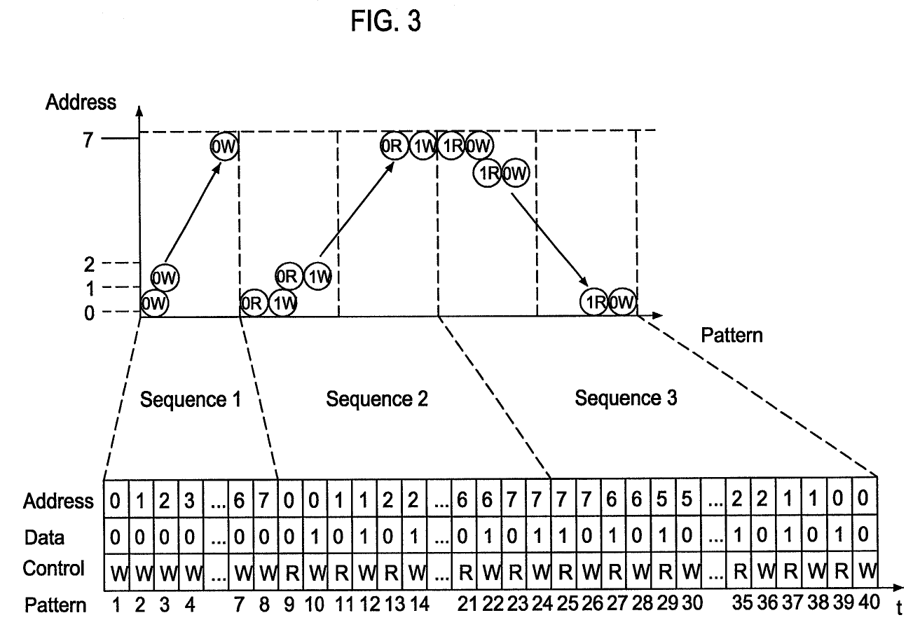

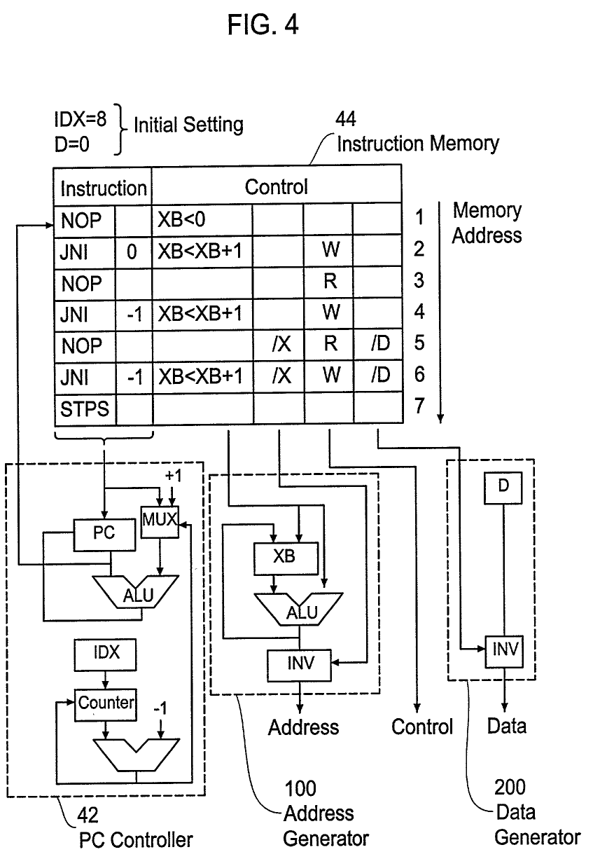

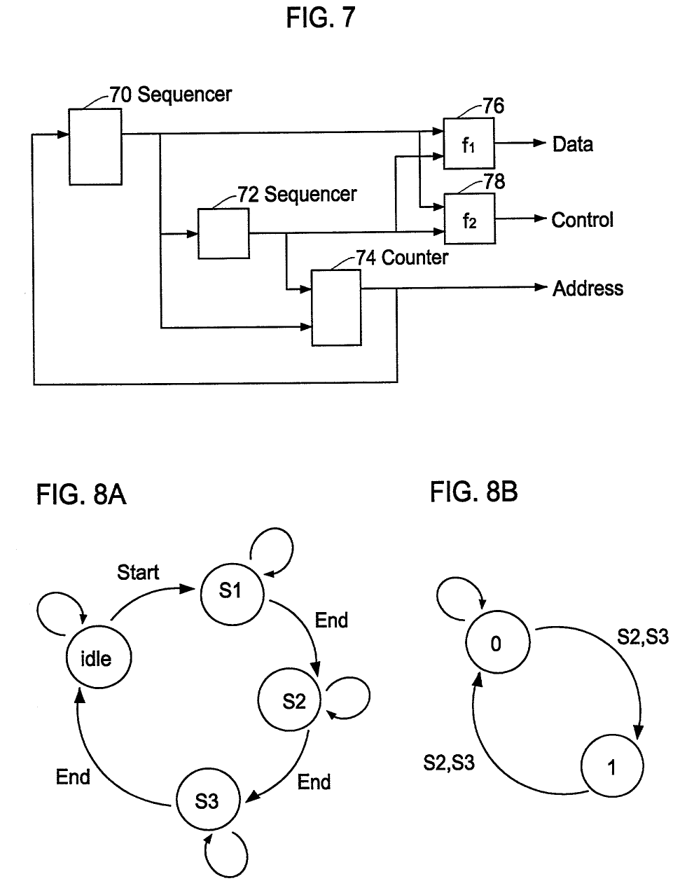

FIG. 7 shows an example of an algorithmic pattern generator of the present invention structured by using an FPGA. The algorithmic pattern generator in this example is structured by sequencers and counters configured by an FPGA to generate the marching pattern shown in FIG. 3. This algorithmic pattern generator can be structured by using programmable logic devices other than the FPGA.

The pattern generator in FIG. 7 has sequencers 70 and 72, a counter 74, and logic circuits 76 and 78. The counter 74 is an up/down counter. The logic circuits 76 and 78 achieve gate functions such as AND and OR. The output of the logic circuit 76 is the data, the output of logic circuit 78 is the control signal, and the output of the counter 74 is the address in FIG. 3. These data, control signal, and address configure the marching test pattern of FIG. 3 which is supplied to the memory device under test.

FIGS. 8A and 8B are state diagrams showing the operational sequences of each part of the algorithmic pattern generator of FIG. 7 structured by the FPGA for generating the marching pattern of FIG. 3. FIG. 8A shows the operation of the sequencer 70, and FIG. 8B shows the operation of the sequencer 72.

The counter 74 is programmed to count upward when the condition (state) of the sequencer 70 is either S1 or S2, and to count downward when the state of the sequencer 70 is S3. The counter 74 is also programmed to not operate (pose) when the state of the sequencer 72 is logic 1, and to conduct a count operation when the state of the sequence 72 is logic 0.

In FIG. 8A, when the start condition is established in an idle state, the sequencer 70 begins its operation where it transitions to the S1 state (sequence 1). Due to this transition, the counter 74 also begins its operation where the clock is counted upward one by one. As a result, the counter 74 generates the addresses from 0 to 7 (patterns 1-8) shown in FIG. 3.

The sequencer 72 in FIG. 8B repeatedly alternates between logic 0 and logic 1 when the state of the sequencer 70 is either in S2 or S3, however, it is programmed to not operate when the state of the sequence 70 is S1. Thus, the sequencer 72 is inoperable, where it maintains the logic 0. This logic 0 is output from logic circuit 76 as the data, thus, the write data 0 in the patterns 1-8 in FIG. 3 is formed. This logic 0 is also output from the logic circuit 78 as the write control signal (W).

In FIG. 8A, when the sequence 1 of FIG. 3 ends, an end state is established where the sequencer 70 transitions to state S2 (sequence 2). The counter 74, as mentioned above, is set to count upward even when the state of sequencer 70 is in S2. Therefore, the address value increases as shown in the sequence 2 of FIG. 3.

At this time, as shown in FIG. 8B, the sequencer 72 synchronizes with the clock and repeatedly changes between the logic 0 and logic 1 when the state of the sequencer 70 is either in S2 or S3. Since the operation of the counter 74 stops when the state of the sequencer 72 is logic 1 as mentioned above, the address output from the counter 74 maintains the previous state. Therefore, the address output of the counter 74 increases while repeating the same address twice, such as “00112233 . . . ” as shown in FIG. 3.

Since the state of the sequencer 72 repeatedly changes between the logic 0 and logic 1, the output of the sequencer 72 is output from the logic circuit 78 as the write control signal (W) and the read control signal (R). The state of the sequencer 72 also outputs logic 0 and logic 1 from the logic circuit 76 as the data shown in FIG. 3.

In FIG. 8A, when the sequence 2 of FIG. 3 ends, an end state is established where the sequencer 70 transitions to state S3 (sequence 3). In the state S3, as mentioned above, the address value decreases from the address 7 to address 0 since the counter 74 downward counts the clock. Since the sequencer 72 at this time repeatedly changes between the logic 0 and logic 1, as explained above, the address output of the counter 74 decreases while repeating the same address twice, such as “77665544 . . . ” as shown in FIG. 3.

Further, the state of the sequencer 72 repeatedly changes between the logic 0 and logic 1, which is output from the logic circuit 78 as the write control signal (W) and the read control signal (R), as well as output from the logic circuit 76 as the data. At this time, since the data and control signals (write and read) are opposite to that of the sequence 2, an inverse logic is output from the logic circuits 76 and 78 in, for example, the state S3 of the sequencer 70.

As described in the foregoing, the marching test pattern of FIG. 3 can be generated by the algorithmic pattern generator of FIG. 7. In this manner, by creating an algorithmic pattern generator with a programmable logic device, an exclusive pattern generator for specific patterns can be structured with a small scale hardware. Further, since this pattern generator conducts an operation predetermined by the program assembled in the hardware, it does not require times for accessing the memory such as involved in the conventional general purpose pattern generator, and therefore is capable of a high-speed operation.

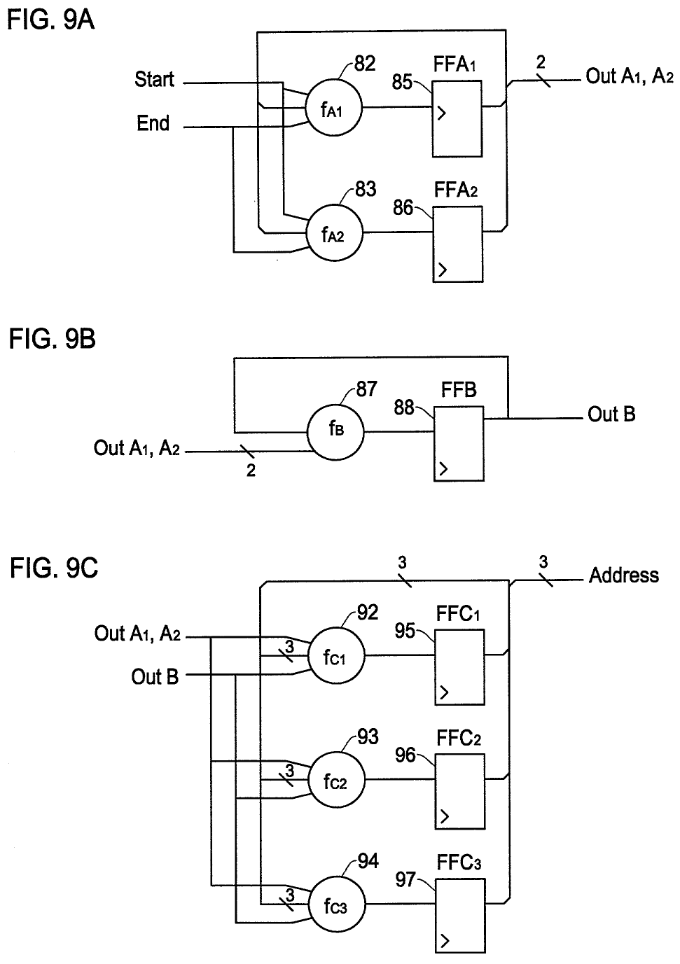

FIG. 9A is a block diagram showing a structural example of the sequencer 70 of FIG. 7, FIG. 9B is a block diagram showing a structural example of the sequencer 72 of FIG. 7, and FIG. 9C is a block diagram showing a structural example of the counter 74 of FIG. 7. These circuits are structured by combinations of the logic circuits and the flip flops in the FPGA.

The sequencer 70 in FIG. 9A is a state machine structured with logic circuits 82 and 83 and flip flops 85 and 86. Based on the program set in the FPGA, the logic circuits 85 and 86 are provided with “Start” and “End” as input conditions. Outputs A1 and A2 of the sequencer 70 are respectively provided to the sequencer 72 and the counter 74 of FIGS. 9B and 9C.

The sequencer 72 in FIG. 9B is a state machine structured with a logic circuit 87 and a flip flop 88. The output of the sequencer 70 is provided to the input of the sequencer 72. As explained above, when the sequencer 70 is in the S1 state, the sequencer 72 is set to be inoperable (pose).

The counter 74 in FIG. 9C is structured with logic circuits 92, 93 and 94 and flip flops 95, 96 and 97. The output of the counter 74 is the address provided to the memory under test. When the output from the sequencer 72 is in logic 1, the counting operation of the counter 74 becomes inoperable (pose).

The marching test pattern in the above explanation is used just as an example, however, the algorithmic pattern generator of the present invention can be reconfigured to generate other type of algorithmic pattern when a reprogrammable logic device is used, since the program in such FPGA can be changed.

Typically, the FPGA program is conducted by using hardware description language (ex. VHDL, etc.). Therefore, the pattern generator of the present invention can be programmed by using the existing VHDL tools. However, since general purpose algorithmic pattern generators structured to generate various algorithmic patterns already exist, FPGA programming can be performed by creating a compiler for converting the existing programs of the general purpose pattern generator into the FPGA programs. In this way, the program resources in the existing general purpose pattern generator can be effectively utilized.

Further, the algorithmic pattern generator of the present invention can be structured in a small scale hardware such as by one silicon chip. Therefore, by installing the algorithmic pattern generator close to the memory device under test, for example, adjacent to the drivers (pin electronics) in the semiconductor memory test system, the signal paths can be shortened, and as a consequence, high-speed test patterns can be applied to the memory under test.

As explained above, by forming the algorithmic pattern generator of the present invention with a programmable logic device, a dedicated pattern generator for generating only the specific test patterns can be structured by a small scale hardware. Further, since the algorithmic pattern generator of the present invention conducts a predetermined operation by the program assembled in the hardware, time to access the memory that is required in the conventional general purpose pattern generator is no longer required. Therefore, the pattern generator of the present invention can operate at high-speed. In addition, by using a programmable logic device capable of repeatedly writing the programs, the algorithmic pattern generator of the present invention can be reconfigured to change the algorithmic patterns to be generated by changing the hardware program.

Although the invention is described herein with reference to the preferred embodiment, one skilled in the art will readily appreciate that various modifications and variations may be made without departing from the spirit and scope of the present invention. Such modifications and variations are considered to be within the purview and scope of the appended claims and their equivalents.

What is claimed is:

1. An algorithmic test pattern generator for use in a semiconductor memory test system for generating test patterns to test semiconductor memory devices, comprising:
a field programmable logic device wherein at least one state machine is configured by applying a hardware based program thereto, thereby enabling to generate specified algorithmic test patterns.

2. An algorithmic test pattern generator as defined in claim 1, wherein said field programmable logic device includes a plurality of synchronous circuit units each being structured by combinations of logic circuits and flip flops, and wherein said state machine is configured by combining the synchronous circuit units through a hardware program.

3. An algorithmic test pattern generator as defined in claim 1, wherein said hardware program applied to the field programmable logic device is rewritable, thereby creating a pattern generator of different structure for generating a different algorithmic pattern.
